(19) United States
(12) Patent Application Publication
(10) Pub. No.: US 2022/0285464 A1
(43) Pub. Date: Sep. 8, 2022

(54) DISPLAY PANEL AND METHOD FOR MANUFACTURING SAME, AND DISPLAY DEVICE

(71) Applicants: Chengdu BOE Optoelectronics Technology Co., Ltd, Chengdu (CN); BOE Technology Group Co., Ltd, Beijing (CN)

(72) Inventors: Erjin Zhao, Beijing (CN); Zhiliang Jiang, Beijing (CN); Qilin Lei, Beijing (CN); Shifeng Gan, Beijing (CN)

(21) Appl. No.: 17/753,000

(22) Filed: May 25, 2022

Related U.S. Application Data
(63) Continuation of application No. 16/622,407, filed on Dec. 13, 2019.

(30) Foreign Application Priority Data
Mar. 28, 2018 (CN) 201810265553.8

(51) Int. Cl. H01L 27/32; H01L 51/00; H01L 51/52; H01L 51/56

(52) U.S. Cl. CPC H01L 27/3244; H01L 51/0097; H01L 51/5253; H01L 51/56; H01L 2227/323; H01L 2251/5338; H01L 2251/558; H01L 2227/326

(57) ABSTRACT

The present disclosure provides a display panel and a method for manufacturing the same, and a display device, pertaining to the field of display technologies. The display panel includes a first panel region and a second panel region; wherein the first panel region is configured to emit light, the second panel region has a light-emitting function different from that of the first panel region, and the second panel region includes a target region, the target region having a thickness less than that of the first panel region. According to the present disclosure, the problem that film layers in the light-emitting region of the display panel are subject to fractures may be solved, the probability of cracks or fractures of the film layers in the light-emitting region of the display panel may be lowered. The present disclosure is applicable to display panels.

This application is a continuation of U.S. application Ser. No. 16/622,407, filed on Dec. 13, 2019, which is a 371 of PCT patent application number PCT/CN2019/079639 filed on Mar. 26, 2019, which claims priority to Chinese Patent Application No. 201810265553.8, filed on Mar. 28, 2018 and entitled “DISPLAY PANEL AND METHOD FOR MANUFACTURING SAME, AND DISPLAY DEVICE”, the entire contents of which are incorporated herein by reference

### TECHNICAL FIELD

The present disclosure relates to the field of display technologies, and in particular, relates to a display panel and a method for manufacturing the same, and a display device.

### BACKGROUND

With the development of display technologies, a variety of display panels are available, for example, a flexible organic light-emitting diode (OLED) display panel.

The flexible OLED display panel displays an image by light emission from a plurality of OLEDs. In the flexible OLED display panel, a region where the OLEDs are disposed is referred to as a light-emitting region, and a region other than this light-emitting region is referred to as a non-light-emitting region. The flexible OLED display panel is formed by superimposing a plurality of functional layers. Some of the plurality of functional layers form the OLEDs.

### SUMMARY

Embodiments of the present disclosure provide a display panel and a method for manufacturing the same, and a display device. The technical solutions are as follows.

In a first aspect, a display panel is provided. The display panel comprises a first panel region and a second panel region; wherein the first panel region is configured to emit light, the second panel region has a light-emitting function different from that of the first panel region, and the second panel region comprises a target region, the target region having a thickness less than that of the first panel region.

Optionally, the display panel comprises at least one target functional layer; wherein a surface of a portion of the target functional layer in the target region comprises at least one groove.

Optionally, the groove is in an elongated strip shape, and a first cross section of the groove is in a rectangular shape or a trapezoid shape, the first cross section being parallel to a thicknesswise direction of the target functional layer and perpendicular to a lengthwise direction of the groove.

Optionally, a depth of the groove is in a value range from 500 nm to 50 μm, a width of an opening surface of the groove is less than or equal to 10 μm, and a depth direction of the groove is parallel to the thicknesswise direction of the target functional layer.

Optionally, the display panel comprises a plurality of functional layers that are stacked; wherein the target function layer is a functional layer proximal to an outer side in the plurality of functional layers.

Optionally, the plurality of functional layers comprise a base layer, a display film layer, an encapsulation layer and a polarization layer that are stacked in sequence, the base layer and the encapsulation layer being both the target functional layers.

Optionally, the display film layer comprises a first insulating layer, a semiconductor layer, a gate insulating layer, a gate, a second insulating layer, a source and drain layer, a planarization layer, a first electrode, a pixel defining layer, a light-emitting functional layer and a second electrode that are disposed between the base layer and the encapsulation layer along a direction distal from the base layer.

Optionally, the display panel comprises a light-emitting unit and a pixel circuit; wherein the light-emitting unit and the pixel circuit are both in the first panel region.

Optionally, the display panel is an electroluminescent display panel, and the light-emitting unit is an electroluminescent unit.

Optionally, the display panel is an OLED display panel, and the light-emitting unit is an OLED; or the display panel is a QLED display panel, and the light-emitting unit is a QLED.

Optionally, the first panel region is a light-emitting region, and the second panel region is a non-light-emitting region.

Optionally, the display panel is a flexible display panel.

In a second aspect, there is provided a method for manufacturing a display panel. The method comprises:
manufacturing a display panel, the display panel comprising a first panel region and a second panel region; wherein the first panel region is configured to emit light, the second panel region has a light-emitting function different from that of the first panel region, and the second panel region comprises a target region, the target region having a thickness less than that of the first panel region.

Optionally, the manufacturing a display panel comprises:
forming a plurality of functional layers that are stacked; wherein the plurality of functional layers comprise at least one target functional layer, a surface of a portion of the target functional layer in the target region being provided with at least one groove.

Optionally, the forming a plurality of functional layers that are stacked comprises:
providing a base substrate; wherein the base substrate comprises a first substrate region and a second substrate region, the second substrate region protruding from the first substrate region, and the second substrate region being provided with at least one protrusion;
forming a base layer on a surface of the base substrate where the at least one protrusion is; wherein a thickness of a portion of the base layer in the second substrate region is less than a thickness of a portion of the base layer in the first substrate region, a surface, distal from the base substrate, in surfaces of the base layer is a flat surface, and a surface, proximal to the base substrate, in the surfaces of the base layer is provided with at least one groove, the at least one groove being in one-to-one correspondence with the at least one protrusion;
forming a display film layer on a side of the base layer distal from the base substrate;
forming an encapsulation layer on a side of the display film layer distal from the base layer, wherein a surface of the encapsulation layer distal from the display film layer is provided with at least one groove, an orthographic projection of the at least one groove on the base substrate being in the second substrate region;
forming a polarization layer on a side of the encapsulation layer distal from the display film layer, wherein the base layer, the display film layer, the encapsulation layer and the polarization layer form the plurality of functional layers, and the base layer and the encapsulation layer are both the target functional layers; and
stripping off the base substrate.

Optionally, the forming an encapsulation layer on a side of the display film layer distal from the base layer, a surface of the encapsulation layer distal from the display film layer being provided with at least one groove comprises:
forming an encapsulation material layer on the side of the display film layer distal from the base layer; and
forming at least one groove on a surface of the encapsulation material layer distal from the display film layer to obtain the encapsulation layer.

In a third aspect, a display device is provided. The display device comprises: a display panel, the display panel comprising a first panel region and a second panel region; wherein the first panel region is configured to emit light, the second panel region has a light-emitting function different from that of the first panel region, and the second panel region comprises a target region, the target region having a thickness less than that of the first panel region.

Optionally, the display panel further comprises a light-emitting unit and a pixel circuit; wherein the light-emitting unit and the pixel circuit are both in the first panel region.

Optionally, the display device is an electroluminescent display device, and the light-emitting unit is an electroluminescent unit.

Optionally, the display device is an OLED display device, and the light-emitting unit is an OLED; or the display device is a QLED display device, and the light-emitting unit is a QLED.

Optionally, the first panel region is a light-emitting region, and the second panel region is a non-light-emitting region.

Optionally, the display device is a flexible display device

The technical solutions according to the embodiments of the present disclosure achieve the following beneficial effects:

In the display panel, the method for manufacturing the same, and the display device according to the embodiments of the present disclosure, the display panel includes a first panel region and a second panel region; wherein the first panel region is configured to emit light, the second panel region has a light-emitting function different from that of the first panel region, and the second panel region comprises a target region. The target region has a thickness less than that of the first panel region. In this way, when the display panel is bent, the stress on the display panel may concentrate towards the second panel region, such that the stress on the first panel region may be reduced. This facilitates lowering of the probability that cracks may be caused to film layers in the first panel region, and avoids adverse impacts on the display effect of the display panel caused by cracks of the film layers in the first panel region.

### BRIEF DESCRIPTION OF THE DRAWINGS

In order to describe the technical solutions in the embodiments of the present disclosure more clearly, the accompanying drawings required for describing the embodiments are introduced briefly as follows. Apparently, the accompanying drawings in the following description show merely some embodiments of the present disclosure, and a person of ordinary skill in the art may also derive other drawings from these accompanying drawings without any creative effort.

FIG. 1 is a schematic structural diagram of a display panel according to an embodiment of the present disclosure;

FIG. 2 is a schematic diagram illustrating bending of a display panel according to an embodiment of the present disclosure;

FIG. 3 is a schematic structural diagram of another display panel according to an embodiment of the present disclosure;

FIG. 4 is a flowchart of a method for manufacturing a display panel according to an embodiment of the present disclosure; and

FIG. 5 to FIG. 9 are schematic diagrams of a manufacturing process of a display panel according to an embodiment of the present disclosure.

### DETAILED DESCRIPTION

Hereinafter, the embodiments of the present disclosure will be described with reference to the accompanying drawings, to make the principles of the present disclosure more clearly.

A flexible OLED display panel is a display panel which is not only capable of displaying images, but also capable of being bent. Great stress may be generated during bending of the flexible OLED display panel, so that the flexible OLED display panel may be subject to film layer separation. This may further result in cracks or fractures of the film layers of the flexible OLED display panel. However, the cracks or fractures of the film layers in the light-emitting region may exert an adverse impact on the display effect of the flexible OLED display panel.

Embodiments of the present disclosure provide a display panel and a manufacturing method thereof, and a display device, which may lower the probability that cracks or fractures may occur in film layers in the light-emitting region of the display panel, and thus may lower the probability of the fractures of the film layers in the light-emitting region. Details of the technical solutions of the present disclosure may be referenced to the following embodiments.

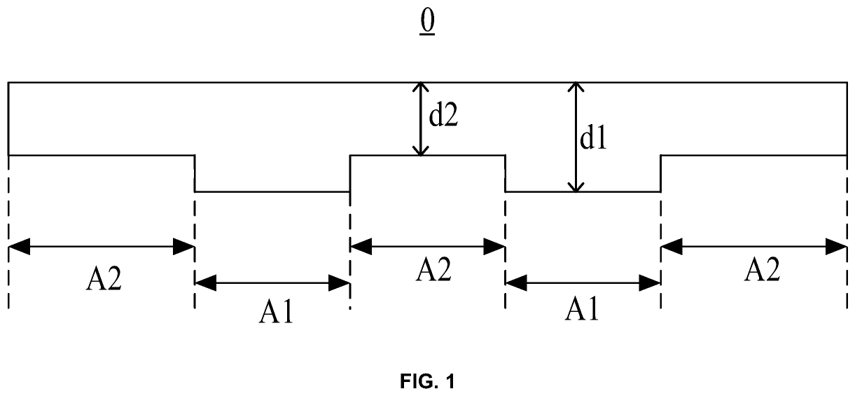

Exemplarily, FIG. 1 is a schematic structural diagram of a display panel 0 according to an embodiment of the present disclosure. As illustrated in FIG. 1, the display panel 0 may include a first panel region A1 and a second panel region A2. The first panel region A1 is configured to emit light. The second panel region A2 has a light-emitting function different from that of the first panel region A1. The second panel region A2 includes a target region (not illustrated in FIG. 1). The target region has a thickness that is less than that of the first panel region A1. As illustrated in FIG. 1, description is given using the scenario where the second panel region A2 is the target region as an example, and in this case, the thickness of the target region is less than the that of the first panel region A1, that is, the thickness of the second panel region A2 is less than that of the first panel region A1. The thickness d1 of the first panel region A1 is the dimension of the first panel region A1 in the direction perpendicular to the panel surface (not illustrated in FIG. 1) of the display panel 0, and the thickness d2 of the second panel region A2 is the dimension of the second panel region A2 in the direction perpendicular to the panel surface of the display panel 0.

In summary, the display panel according to the embodiment of the present disclosure includes a first panel region and a second panel region. The first panel region is configured to emit light, the second panel region has a light-emitting function different from that of the first panel region, and the second panel region includes a target region. The target region has a thickness less than that of the first panel region. In this way, when the display panel is bent, the stress on the display panel may concentrate towards the second panel region, such that the stress on the first panel region may be reduced. This facilitates lowering of the probability that cracks may occur on the film layers in the first panel region (that is, the light-emitting region), and avoids adverse impacts on the display effect of the display panel caused by cracks of the film layers in the first panel region.

Optionally, the display panel 0 may be a flexible display panel, the first panel region A1 may be a light-emitting region, and the second panel region A2 may be a non-light-emitting region. Since the first panel region A1 is a light-emitting region and the second panel region A2 is a non-light-emitting region, the light-emitting function of the first panel region A1 is different from that of the second panel region A2.

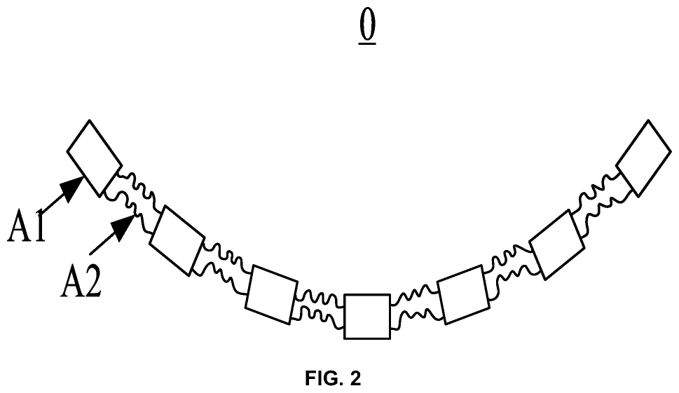

Exemplarily, FIG. 2 is a schematic diagram illustrating bending of a display panel according to an embodiment of the present disclosure. In FIG. 2, description is given using the scenario where the second panel region A2 is the target region (that is, the thickness of any portion in the second panel region A2 is less than that of the first panel region A1) as an example. As illustrated in FIG. 2, since the thickness (not illustrated in FIG. 2) of the second panel region A2 is less than the thickness (not illustrated in FIG. 2) of the first panel region A1, when the display panel 0 is bent, the stress on the display panel 0 may concentrate towards the second panel region A2, such that the stress on the first panel region A1 is reduced. Therefore, in the display panel 0 as illustrated in FIG. 2, the stress on the first panel region A1 is small.

Optionally, the display panel 0 may include a light-emitting unit (not illustrated in FIG. 1 or FIG. 2) and a pixel circuit (not illustrated in FIG. 1 or FIG. 2). The pixel circuit is configured to drive the light-emitting unit to emit light. In the display panel 0, the light-emitting unit and the pixel circuit may be both disposed in the first panel region A1. Since the main structures of the display panel 0 are the light-emitting unit and the pixel circuit, the light-emitting unit and the pixel circuit are both disposed in the first panel region A1, that is, the main structures of the display panel 0 are disposed in the first panel region A1. As such, when the display panel 0 is bent, the probability that cracks or even fractures may be caused to film layers forming the main structures may be lowered, such that adverse impacts on the display effect of the display panel 0 caused by the cracks or fractures of the film layers reduces.

The display panel 0 may be an electroluminescent display panel, and correspondingly, the light-emitting unit may be an electroluminescent unit. Optionally, the display panel is an OLED display panel, and the light-emitting unit is an OLED; or the display panel is a quantum dot light-emitting diode (QLED) display panel, and the light-emitting unit is a QLED. The OLED display panel may be an active matrix organic light-emitting diode (AMOLED) display panel or a passive matrix organic light-emitting diode (PMOLED) display panel. It may be easily understood that examples of the display panel in the embodiments of the present disclosure are only exemplary. The display panel 0 may also be other light-emitting display panel, and the display panel 0 may also be other flexible display panel, or may not be a flexible display substrate, which is not limited in the embodiments of the present disclosure.

Optionally, the display panel 0 may include at least one target functional layer (not illustrated in FIG. 1 or FIG. 2). The surface of a portion of the target functional layer disposed in the target region includes at least one groove. The groove can reduce the thickness of the target region. In addition, in an aspect, the groove can enhance the flexibility of the second panel region A2, and increase the external load applied to the second panel region A2 when the display panel 0 is bent, such that the deformation of the second panel region A2 is increased. In this way, the external load applied to the first panel region A1 is reduced, such that the deformation of the first panel region A1 is also reduced (that is, the deformation of the first panel region A1 is reduced by increasing the deformation of the second panel region A2), and thus the probability of fractures of the film layers in the first panel region A1 is reduced. In another aspect, when cracks occur to the second panel region A2, the groove can effectively prevent the cracks from expanding towards the first panel region A1, thereby prolonging the life time of the device.

Optionally, the groove may be in an elongated strip shape, and a first cross section of the groove may be in a rectangular or trapezoid shape. The first cross section of the groove is parallel to the thicknesswise direction of the target functional layer and perpendicular to the lengthwise direction of the groove. The depth of the groove takes a value in the range of 500 nm to 50 μm. For example, the depth of the groove may be 600 nm, 800 nm, 20 μm, 30 μm or the like. The opening face of the groove may have a width less than or equal to 10 μm. For example, the width of the opening face of the groove may be 3 μm, 5 μm, 8 μm or the like. The depthwise direction of the groove is parallel to the thicknesswise direction of the target functional layer.

Optionally, the display panel 0 may include a plurality of functional layers that are stacked. The target functional layer may be a functional layer proximal to an outer side in the plurality of functional layers. For example, the target functional layer is a functional layer on an outermost side in the plurality of functional layers. When the target functional layer is the functional layer proximal to the outer side in the plurality of functional layers, it is convenient to form a groove on the target functional layer.

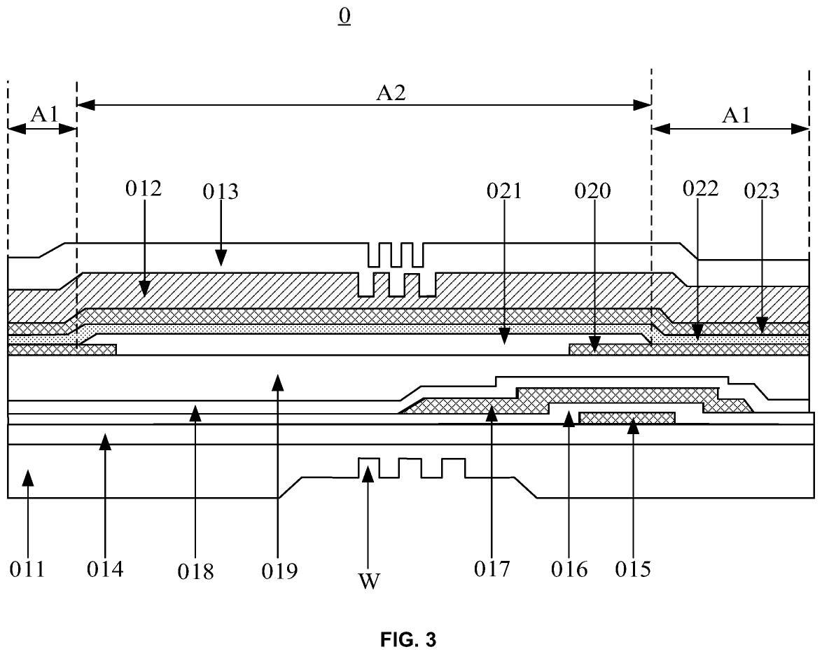

Optionally, FIG. 3 is a schematic structural diagram of another display panel 0 according to an embodiment of the present disclosure. As illustrated in FIG. 3, the display panel 0 includes a plurality of functional layers that are stacked. The plurality of functional layers may include a base layer 011, a display film layer (not illustrated in FIG. 3), an encapsulation layer 012 and a polarization layer 031 that are stacked in sequence. The base layer 011 and the encapsulation layer 012 are both the target functional layers. At least one groove W is formed on both the surface of a portion, in the target region, of the side of the base layer 011 distal from the display film layer (the target region is a region having a smaller thickness in the second panel region A2, which is not illustrated in FIG. 3) and the surface of a portion, in the target region, of the side of the encapsulation layer 012 distal from the display film layer. In FIG. 3, description is given using the scenario where the base layer 011 and the encapsulation layer 012 are both provided with three grooves W and the first cross section of the groove W is in a rectangular shape as an example. The polarization layer 013 may be attached on a side of the encapsulation layer 012 distal from the display film layer.

Optionally, as illustrated in FIG. 3, the display film layer includes a first insulating layer 014, a semiconductor layer 015, a gate insulating layer 016, a gate 017, a second insulating layer 018, a source and drain layer (not illustrated in FIG. 3), a planarization layer 019, a first electrode 020, a pixel defining layer 021, a light-emitting functional layer 022 and a second electrode 023 that are disposed between the base layer 011 and the encapsulation layer 012 along a direction distal from the base layer 011. The semiconductor layer 015, the gate insulating layer 016, the gate 017, the second insulating layer 018 and the source and drain layer form a thin film transistor (TFT). The TFT may be part of the pixel circuit. Parts of the first electrode 020, the light-emitting functional layer 022 and the second electrode 023 that are in contact with each other and stacked to each other form a light-emitting unit. The pixel defining layer 021 is configured to define a pixel opening, and the light-emitting unit is disposed in the pixel opening. One of the first electrode 020 and the second electrode 023 may be an anode, and the other thereof may be a cathode. The planarization layer 019 is configured to absorb concaves and convexes on the surface of the base layer 011 where the TFT is formed, such that the surface of the base layer 011 where the TFT is formed is planarized, which facilitates fabrication of the light-emitting unit.

Optionally, in the display panel 0, the base layer 011 may be a film layer formed from an organic polymer material, such as polyimide or the like or an organic polymer material mixed with glass fiber particles by dip coating, ink jetting, spin coating or the like. Alternatively, the base layer 011 may be directly formed by using a template (the base layer 011 is formed by using a template having the same shape as the base layer 011). The first insulating layer 014 may be a single-layer or multi-layer structure formed from an inorganic compound, such as silicon nitride, silicon oxide or the like, by chemical vapor deposition (CVD). The semiconductor layer 015 may be a film layer structure formed from a silicon-oxygen semiconductor by CVD. The gate insulating layer 016 may be a single-layer or multi-layer structure formed from an inorganic compound, such as silicon nitride, silicon oxide or the like by CVD. The gate 017 may be a single-layer or multi-layer structure formed from a metal material, such as copper, aluminum, molybdenum, tungsten or the like by sputtering or CVD. The second insulating layer 018 may be a single-layer or multi-layer structure formed from an inorganic compound, such as silicon nitride, silicon oxide or the like by CVD. The planarization layer 019 may be a film layer structure formed from an organic polymer material, such as polyimide, epoxy resin or the like by dip coating, ink jetting, spin coating or the like. The first electrode 020 may be a single-layer or multi-layer structure formed from a metal material, such as silver, aluminum or the like or formed from metal oxide, such as indium tin oxide (ITO), indium zinc oxide (IZO) or aluminum-doped zinc oxide (ZnO:Al) or the like, by sputtering or the like process. The pixel defining layer 021 may be a film layer formed from an organic polymer material, such as polyimide, epoxy resin or the like by dip coating, ink jetting, spin coating or the like. The light-emitting functional layer 022 may be a multi-layer structure formed by ink jetting, spin coating, evaporation or the like. The second electrode 023 may be a film layer structure formed from a metal material, such as silver, aluminum or the like by sputtering, evaporation or the like. The encapsulation layer 012 may be a single-layer or multi-layer structure formed from an inorganic compound, such as silicon nitride, silicon oxide or the like by CVD, spin coating, sputtering, ink jetting or the like.

A person skilled in the art may readily understand that the embodiment of the present disclosure only exemplarily describes the structure of the display panel. In practice, the display panel may include more or fewer structures than the display panel according to the embodiment of the present disclosure. For example, the display panel used in practice may not include the polarization layer as long as it is ensured that the target region is present in the second panel region of the display panel. The details are not given any further in the embodiment of the present disclosure.

In summary, the display panel according to the embodiment of the present disclosure includes a first panel region and a second panel region. The first panel region is configured to emit light, the second panel region has a light-emitting function different from that of the first panel region, and the second panel region includes a target region. The target region has a thickness less than that of the first panel region. In this way, when the display panel is bent, the stress on the display panel may concentrate towards the second panel region, such that the stress on the first panel region is reduced. This facilitates lowering of the probability that cracks may occur on the film layers in the first panel region, and avoids adverse impacts on the display effect of the display panel caused by cracks of the film layers in the first panel region, thereby prolonging the life time of the display panel.

Based on the same inventive concept, an embodiment of the present disclosure provides a method for manufacturing a display panel. The method may be employed to manufacture the display panel according to the above embodiment. Exemplarily, the method for manufacturing a display panel may include: manufacturing a display panel. The display panel includes a first panel region and a second panel region. The first panel region is configured to emit light, the second panel region has a light-emitting function different from that of the first panel region, and the second panel region includes a target region. The target region has a thickness less than that of the first panel region.

In summary, the embodiment of the present disclosure provides a method for manufacturing a display panel. The display panel manufactured by using this method includes a first panel region and a second panel region; wherein the first panel region is configured to emit light, the second panel region has a light-emitting function different from that of the first panel region, and the second panel region includes a target region. The target region has a thickness less than that of the first panel region. In this way, when the display panel is bent, the stress on the display panel may concentrate towards the second panel region, such that the stress on the first panel region is reduced. This facilitates lowering of the probability that cracks may occur on the film layers in the first panel region, and avoids adverse impacts on the display effect of the display panel caused by cracks of the film layers in the first panel region.

Optionally, manufacturing a display panel may include: forming a plurality of functional layers that are stacked; wherein the plurality of functional layers include at least one target functional layer. A surface of a portion of the target functional layer disposed in the target region includes at least one groove.

Optionally, forming a plurality of functional layers that are stacked includes:
providing a first base substrate; wherein the base substrate includes a first substrate region and a second substrate region, the second substrate region protruding from the first substrate region, and the second substrate region being provided with at least one protrusion;
forming a substrate layer on a surface of the base substrate where the at least one protrusion is formed; wherein a thickness of a portion of the base layer in the second substrate region is less than the thickness of a portion of the base layer in the first substrate region, the surface, distal from the base substrate, in surfaces of the base layer is a flat surface, and the surface, proximal to the base substrate, in the surfaces of the base layer is provided with at least one groove, the at least one groove being in one-to-one correspondence with the at least one protrusion;
forming a display film layer on a side of the base layer distal from the base substrate.
forming an encapsulation layer on a side of the display film layer distal from the base layer, wherein a surface of the encapsulation layer distal from the display film layer is provided with at least one groove, and an orthographic projection the at least one groove on the base substrate is in the second substrate region;
forming a polarization layer on a side of the encapsulation layer distal from the display film layer, wherein the base layer, the display film layer, the encapsulation layer and the polarization layer form a plurality of functional layers, and the base layer and the encapsulation layer are both the target functional layers; and
stripping off the base substrate.

Optionally, forming an encapsulation layer on a side of the display film layer distal from the base layer, wherein a surface of the encapsulation layer distal from the display film layer is provided with at least one groove, includes:
forming an encapsulation material layer on the side of the display film layer distal from the base layer; and
forming at least one groove on a surface of the encapsulation material layer distal from the display film layer to obtain the encapsulation layer.

All the above optional technical solutions may form optional embodiments of the present disclosure in any combination, which are not described herein any further.

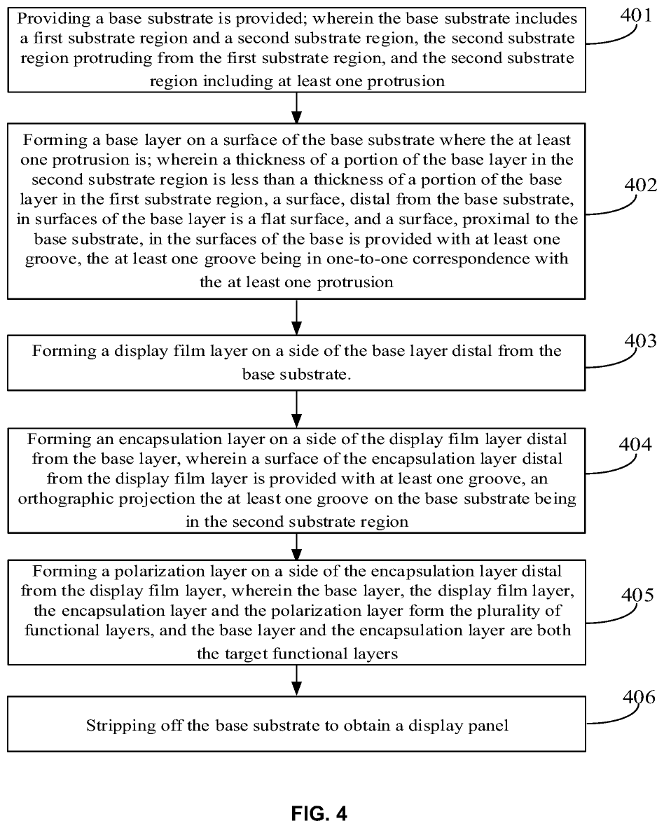

Exemplarily, FIG. 4 is a flowchart of a method for manufacturing a display panel according to an embodiment of the present disclosure. The method may be employed to manufacture the display panel according to the above embodiment. This embodiment is described using manufacturing of the display panel as illustrated in FIG. 3 as an example. As illustrated in FIG. 4, the method for manufacturing a display panel may include the following steps.

In step 401, a base substrate is provided; wherein the base substrate includes a first substrate region and a second substrate region, the second substrate region protruding from the first substrate region, and the second substrate region including at least one protrusion.

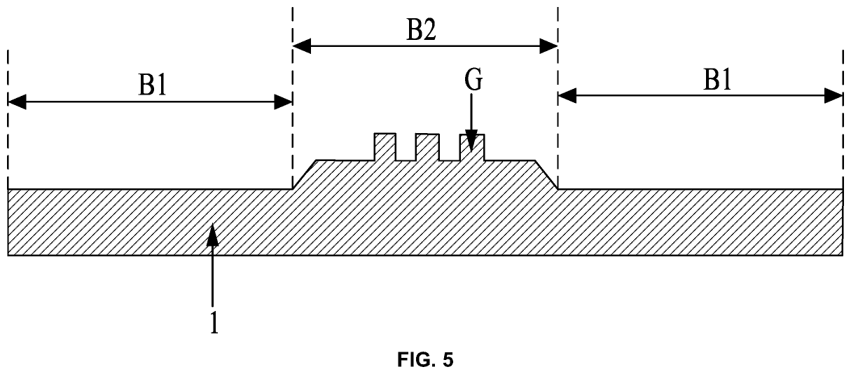

As illustrated in FIG. 5, a schematic structural diagram of a base substrate 1 according to an embodiment of the present disclosure is shown. The base substrate 1 includes a first substrate region B1 and a second substrate region B2. The second substrate region B2 protrudes from the first substrate region B1, and the second substrate region B2 is provided with at least one protrusion G. For example, as illustrated in FIG. 5, the second substrate region B2 is provided with three protrusions G.

The base substrate 1 may be made of an inorganic material, such as quartz, ceramics, glass or the like, or the base substrate 1 may be made of a metal material. The base substrate 1 as illustrated in FIG. 5 may be formed by etching a plate-shaped substrate, or the base substrate 1 as illustrated in FIG. 5 may be formed by arranging protrusions on a plate-shaped substrate.

In step 402, a base layer is formed on a surface of the base substrate where the at least one protrusion is; wherein a thickness of a portion of the base layer in the second substrate region is less than a thickness of a portion of the base layer in the first substrate region, a surface, distal from the base substrate, in surfaces of the base layer is a flat surface, and a surface, proximal to the base substrate, in the surfaces of the base is provided with at least one groove, the at least one groove being in one-to-one correspondence with the at least one protrusion.

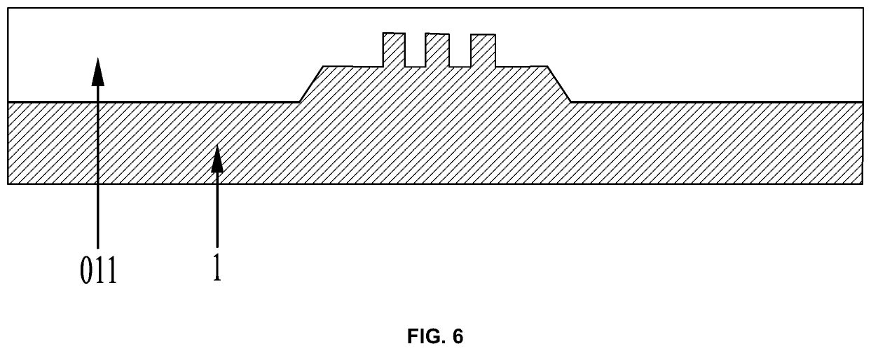

As illustrated in FIG. 6, a schematic diagram after a base layer 011 is formed on the surface of the base substrate 1 provided with protrusions according to an embodiment of the present disclosure is shown. Referring to FIG. 5 and FIG. 6, the thickness of a portion of the base layer 011 in the second substrate region B2 is less than the thickness of a portion of the base layer 011 in the first substrate region B1. Among surfaces of the base layer 011, a surface distal from the base substrate 1 is a flat surface, and a surface proximal to the base substrate 1 is provided with at least one groove (not illustrated in FIG. 6), wherein the at least one groove is be one-to-one correspondence with the at least one protrusion G on the base substrate 1.

The base layer 011 may be made of an organic polymer material, such as polyimide or the like or an organic polymer mixed with glass fiber particles, and the base layer 011 may be prepared by dip coating, ink jetting, spin coating or the like. Exemplarily, a layer of polyimide material may be formed on the surface of the base substrate 1 provided with protrusions by dip coating, ink jetting or spin coating as the base layer 011.

In step 403, a display film layer is formed on a side of the base layer distal from the base substrate.

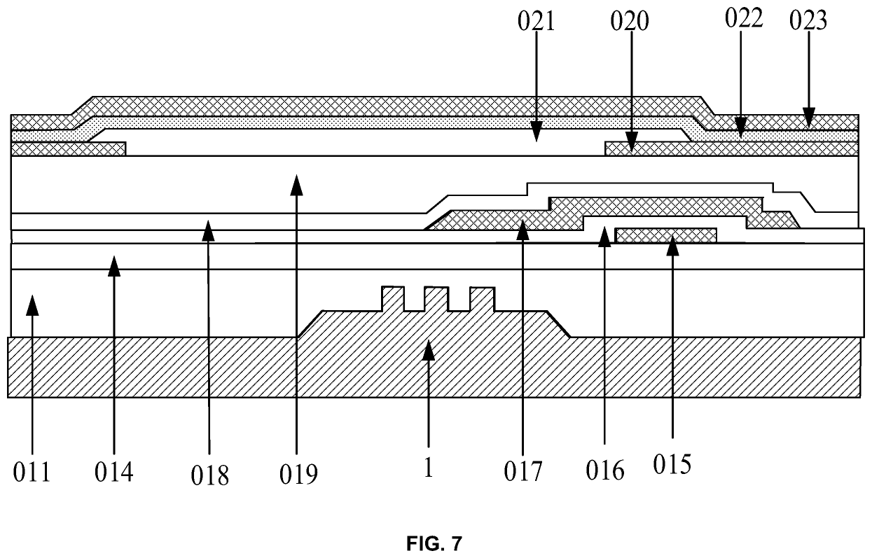

As illustrated in FIG. 7, a schematic diagram after a display film layer is formed on a side of the base layer 011 distal from the base substrate 1 according to an embodiment of the present disclosure is shown. The display film layer includes a first insulating layer 014, a semiconductor layer 015, a gate insulating layer 016, a gate 017, a second insulating layer 018, a source and drain layer (not illustrated in FIG. 7), a planarization layer 019, a first electrode 020, a pixel defining layer 021, a light-emitting functional layer 022 and a second electrode 023 that are disposed in the direction away from the base layer 011. The semiconductor layer 015, the gate insulating layer 016, the gate 017, the second insulating layer 018 and the source-drain layer form a TFT. The TFT belongs to the pixel circuit. Parts of the first electrode 020, the light-emitting functional layer 022 and the second electrode 023 that are in contact with each other and stacked to each other form a light-emitting unit. The pixel defining layer 021 is configured to define a pixel opening, and the light-emitting unit is in the pixel opening. One of the first electrode 020 and the second electrode 023 may be an anode, and the other thereof may be a cathode. The planarization layer 019 is configured to absorb concaves and convexes on the surface of the substrate where the TFT is formed, such that the surface of the substrate where the TFT is formed is planarized, which facilitates preparation of the light-emitting unit.

The first insulating layer 014 may be a single-layer or multi-layer structure formed from an inorganic compound, such as silicon nitride, silicon oxide or the like by CVD. The semiconductor layer 015 may be a film layer structure formed from a silicon-oxygen semiconductor by VCD. The gate insulating layer 016 may be a single-layer or multi-layer structure formed from an inorganic compound such as silicon nitride, silicon oxide or the like by CVD. The gate 017 may be a single-layer or multi-layer structure formed from a metal material, such as copper, aluminum, molybdenum, tungsten or the like by sputtering or CVD. The second insulating layer 018 may be a single-layer or multi-layer structure formed from an inorganic compound, such as silicon nitride, silicon oxide or the like by CVD. The planarization layer 019 may be a film layer structure formed from an organic polymer material, such as polyimide, epoxy resin or the like by dip coating, ink jetting, spin coating or the like. The first electrode 020 may be a single-layer or multi-layer structure formed from a metal material, such as silver, aluminum or the like or formed from a metal oxide, such as ITO, IZO, ZnO:Al or the like by sputtering or the like. The pixel defining layer 021 may be a film layer formed from an organic polymer material, such as polyimide, epoxy resin or the like by dip coating, ink jetting, spin coating or the like. The light-emitting functional layer 022 may be a multi-layer structure formed by ink jetting, spin coating, evaporation or the like. The second electrode 023 may be a film layer structure formed from a metal material, such as silver, aluminum or the like by sputtering, evaporation or the like. The second electrode 023 may be a film layer structure formed from a metal material, such as silver, aluminum or the like by sputtering, evaporation or the like.

In step 404, an encapsulation layer is formed on a side of the display film layer distal from the base layer, wherein a surface of the encapsulation layer distal from the display film layer is provided with at least one groove, an orthographic projection the at least one groove on the base substrate being in the second substrate region.

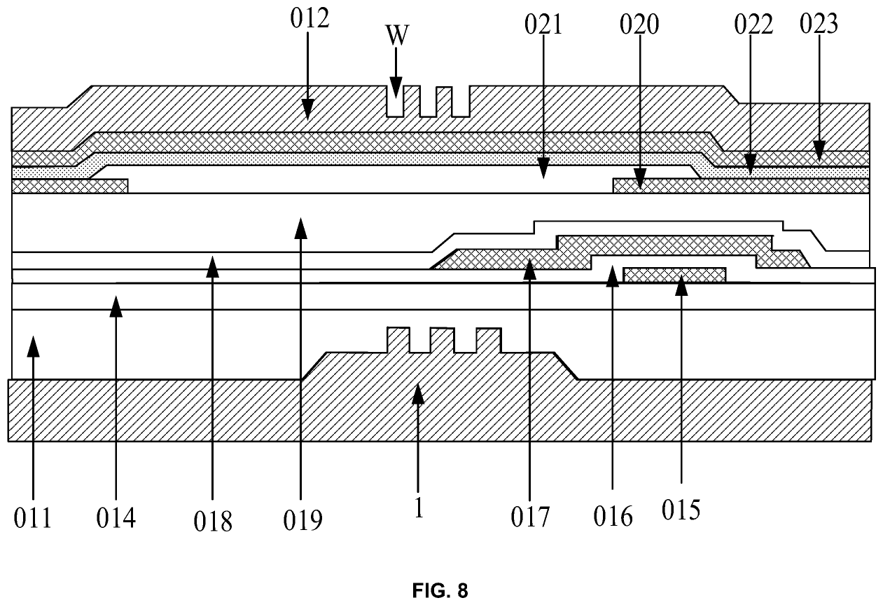

As illustrated in FIG. 8, a schematic diagram after an encapsulation layer 012 is formed on a side of the display film layer distal from the base layer 011 according to an embodiment of the present disclosure is shown. At least one groove W is on a surface of the encapsulation layer 012 distal from the display film layer (not illustrated in FIG. 8). Referring to FIG. 5 and FIG. 8, the orthographic projection of the at least one groove W on the base substrate 1 is in the second substrate region B2. For example, as illustrated in FIG. 8, three grooves W are on the surface of the encapsulation layer 012 distal from the display film layer, wherein the orthographic projections of the three grooves W on the base substrate 1 are in the second substrate region B2.

The encapsulation layer 012 may be a single-layer or multi-layer structure formed from an inorganic compound, such as silicon nitride, silicon oxide or the like by CVD, spin coating, sputtering, ink jetting or the like. Optionally, an encapsulation material layer may be formed on the side of the display film distal from the base layer 011, and then the at least one groove W may be formed on the surface of the encapsulation material layer distal from the display film layer to obtain the encapsulation layer 012. Exemplarily, a layer of silicon nitride may be deposited on the side of the display film layer distal from the base layer 011 by CVD as the encapsulation material layer, and then the encapsulation material layer is processed by a one-time patterning process, such that at least one groove W is formed on the surface of the encapsulation material layer distal from the display film layer.

The one-time patterning process includes photoresist coating, exposure, development, etching and photoresist stripping, and processing the encapsulation material layer by the one-time patterning process may include: coating a layer of photoresist on the encapsulation material layer to form a photoresist layer; exposing the photoresist layer by a mask plate, such that a full-exposure region and a non-exposure region are formed on the photoresist layer; processing the photoresist layer by a development process is performed such that the photoresist in the full-exposure region is totally removed and the photoresist in the non-exposure region is totally remained; etching a region, corresponding to the full-exposure region, on the encapsulation material layer by an etching process to obtain at least one groove W; and finally stripping off the photoresist in the non-exposure region to obtain the encapsulation layer 012.

In step 405, a polarization layer is formed on a side of the encapsulation layer distal from the display film layer, wherein the base layer, the display film layer, the encapsulation layer and the polarization layer form the plurality of functional layers, and the base layer and the encapsulation layer are both the target functional layers.

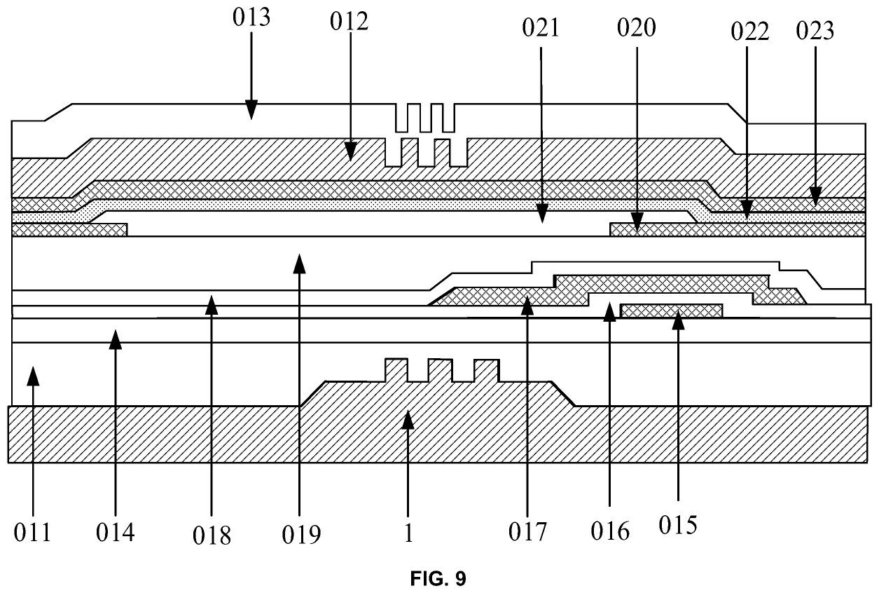

As illustrated in FIG. 9, a schematic diagram after a polarization layer 013 is formed on a side of the encapsulation layer 012 distal from the display film layer according to an embodiment of the present disclosure is shown. The base layer 011, the display film layer, the encapsulation layer 012 and the polarization layer 013 form a plurality of functional layers, and the base layer 011 and the encapsulation layer 012 are both the target functional layers. Exemplarily, a polarization layer 014 may be formed on the side of the encapsulation layer 012 distal from the display film layer by a lamination process. For example, the polarization layer 014 may be attached to the side of the encapsulation layer 012 distal from the display film layer by an optical adhesive, or the polarization layer 014 may be prepared on the side of the encapsulation layer 012 distal from the display film layer by a polarization layer preparation process, which is not limited in the embodiment of the present disclosure.

In step 406, the base substrate is stripped off to obtain a display panel.

A display panel may be obtained after the base substrate 1 is stripped off. A schematic diagram of the display panel may be as illustrated in FIG. 3, and the display panel is formed by a plurality of functional layers that are stacked.

Optionally, the base substrate 1 may be stripped off by mechanical separation or physical separation. Exemplarily, the base substrate 1 may be stripped off by a laser stripping-off process. In practice, the base substrate 1 is irradiated by laser from a side of the base substrate 1 distal from the base layer 011, such that adhesion force between the base layer 011 and the base substrate 1 is removed, and thus the base substrate 1 is stripped off.

A person skilled in the art may readily understand that in the embodiments of the present disclosure, the embodiments of the method for manufacturing a display panel may be referenced to the corresponding embodiments of the display panel. The sequence of the steps in the method for manufacturing a display panel according to the embodiments of the present disclosure may be suitably adjusted, and the steps may be removed or added according to the actual needs. A person skilled in the art would find it ready to envisage variations within the technical disclosure of the present disclosure, and such variations shall fall within the protection scope of the present disclosure, which are thus not described herein any further.

In summary, a method for manufacturing a display panel is provided according to the embodiment of the present disclosure. The display panel manufactured by using this method includes a first panel region and a second panel region; wherein the first panel region is configured to emit light, the second panel region has a light-emitting function different from that of the first panel region, and the second panel region includes a target region, the target region having a thickness less than that of the first panel region. In this way, when the display panel is bent, the stress on the display panel may concentrate towards the second panel region, such that the stress on the first panel region may be reduced. This facilitates lowering of the probability that cracks occur on the film layers in the first panel region, and avoids adverse impacts on the display effect of the display panel caused by cracks on the film layers in the first panel region.

Based on the same inventive concept, an embodiment of the present disclosure provides a display device. The display device includes the display panel as described in the above embodiments. The display panel includes a first panel region and a second panel region; wherein the first panel region is configured to emit light, and the second panel region has a light-emitting function different from that of the first panel region. The second panel region includes a target region, and the target region has a thickness less than that of the first panel region.

Optionally, the display panel includes at least one target functional layer. The surface of a portion of the target functional layer in the target region includes at least one groove.

Optionally, the groove s in an elongated strip shape, and a first cross section of the groove is in a rectangular shape or a trapezoid shape. The first cross section is parallel to the thicknesswise direction of the target functional layer and perpendicular to the lengthwise direction of the groove.

Optionally, the depth of the groove is in a value range of from 500 nm to 50 μm, the width of an opening surface of the groove is less than or equal to 10 μm, and the depthwise direction of the groove is parallel to the thicknesswise direction of the target functional layer.

Optionally, the display panel includes a plurality of functional layers that are stacked. The target function layer is a functional layer proximal to an outer side in the plurality of functional layers.

Optionally, the plurality of functional layers include a base layer, a display film layer, an encapsulation layer and a polarization layer that are stacked in sequence. The base layer and the encapsulation layer are both the target functional layers.

Optionally, the display film layer includes a first insulating layer, a semiconductor layer, a gate insulating layer, a gate, a second insulating layer, a source and drain layer, a planarization layer, a first electrode, a pixel defining layer, a light-emitting functional layer and a second electrode that are disposed between the base layer and the encapsulation layer along a direction distal from the base layer.

Optionally, the display panel includes a light-emitting unit and a pixel circuit. The light-emitting unit and the pixel circuit are both in the first panel region.

Optionally, the display device is an electroluminescent display device, and correspondingly the light-emitting unit is an electroluminescent unit.

Optionally, the display device may be an OLED display device, and correspondingly the light-emitting unit may be an OLED; or the display device may be a QLED display device, and correspondingly the light-emitting unit may be a QLED.

Optionally, the first panel region is a light-emitting region, and the second panel region is a non-light-emitting region.

Optionally, the display device may be a flexible display device.

Optionally, the display device may be a wearable device such as a watch, a bracelet or the like, or may be a mobile terminal such as a mobile phone, a tablet computer or the like, or may be a product or component having the display function, such as a television, a display, a laptop computer, a digital photo frame, a navigator or the like.

It may be readily understood that, for details of the embodiment of the display device according to the present disclosure, reference may be made to the embodiments of the display panel, which are thus not described herein any further.

In summary, a display device is provided according to the embodiment of the present disclosure. The display panel includes a first panel region and a second panel region; wherein the first panel region is configured to emit light, the second panel region has a light-emitting function different from that of the first panel region, and the second panel region includes a target region, the target region having a thickness less than that of the first panel region. In this way, when the display panel is bent, the stress on the display panel may concentrate towards the second panel region, such that the stress on the first panel region may be reduced. This facilitates lowering of the probability that cracks occur on the film layers in the first panel region (that is, the light-emitting region), and avoids adverse impacts on the display effect of the display panel caused by cracks of the film layers in the first panel region.

The foregoing descriptions are merely optional embodiments of the present disclosure, and are not intended to limit the present disclosure. Within the spirit and principles of the present disclosure, any modifications, equivalent substitutions, improvements, etc., are within the protection scope of the present disclosure.

What is claimed is:

1. A display panel, comprising a light-emitting region and a non-light-emitting region, wherein
the non-light-emitting region comprises a target region having a first side edge and a second side edge that are oppositely arranged, a thickness between the first side edge and the second side edge being smaller than a thickness of the light-emitting region along a thickness direction of the display panel; and
a light-emitting unit and a pixel circuit are both disposed in the light-emitting region.

2. The display panel according to claim 1, comprising a plurality of functional layers that are stacked, wherein one or more concave portions are arranged on a surface of a functional layer where the first side edge is located and/or a surface of a functional layer where the second side edge is located.

3. The display panel according to claim 2, wherein the concave portion is in an elongated strip shape, and a boundary of a cross section of the concave portion is composed of at least one arc line segment, or a plurality of straight line segments, or a combination of arc line segments and straight line segments, the cross section being parallel to the thicknesswise direction of the display panel and perpendicular to a lengthwise direction of the concave portion.

4. The display panel according to claim 2, wherein a depth of the concave portion is in a value range from 500 nm to 50 μm, and a depth direction of the concave portion is parallel to the thicknesswise direction of the display panel.

5. The display panel according to claim 2, wherein a width of an opening surface of the concave portion is less than or equal to 10 μm.

6. The display panel according to claim 2, wherein the functional layer where the first side edge is located and the functional layer where the second side edge is located are functional layers proximal to an outer side in the plurality of functional layers.

7. The display panel according to claim 6, wherein the plurality of functional layers comprise a base layer, a display film layer, an encapsulation layer, and a polarization layer that are stacked in sequence, wherein the base layer is the functional layer where the first side edge is located, and the encapsulation layer is the functional layer where the second side edge is located.

8. The display panel according to claim 7, wherein at least one concave portion is formed on a portion, in the target region, of a side of the base layer distal from the display film layer, and at least one concave portion is formed on a portion, in the target region, of a side of the encapsulation layer distal from the display film layer

9. The display panel according to claim 7, wherein the display film layer comprises a first insulating layer, a semiconductor layer, a gate insulating layer, a gate, a second insulating layer, a source and drain layer, a planarization layer, a first electrode, a pixel defining layer, a light-emitting functional layer, and a second electrode that are disposed between the base layer and the encapsulation layer along a direction distal from the base layer.

10. The display panel according to claim 1, wherein the display panel is an electroluminescent display panel, and the light-emitting unit is an electroluminescent unit.

11. The display panel according to claim 10, wherein the display panel is any one of an OLED display panel and a QLED display panel; and correspondingly, the light-emitting unit is any one of an OLED and a QLED.

12. The display panel according to claim 1, wherein the display panel is a flexible display panel.

13. A method for manufacturing a display panel, comprising:
manufacturing a display panel, the display panel comprising a light-emitting region and a non-light-emitting region, wherein the non-light-emitting region comprises a target region having a first side edge and a second side edge that are oppositely arranged, a thickness between the first side edge and the second side edge being smaller than a thickness of the light-emitting region along a thickness direction of the display panel; and a light-emitting unit and a pixel circuit are both disposed in the light-emitting region.

14. The method according to claim 13, wherein said manufacturing the display panel comprises:
forming a plurality of functional layers that are stacked, wherein one or more concave portions are arranged on a surface of a functional layer where the first side edge is located and/or a surface of a functional layer where the second side edge is located.

15. The method according to claim 14, wherein said forming the plurality of functional layers that are stacked comprises:
providing a base substrate, wherein the base substrate comprises a first region and a second region, the second region protruding from the first region, and the second region being provided with at least one convex portion;
forming a base layer on a surface of the base substrate where the at least one convex portion is located, wherein a thickness of a portion of the base layer in the second region is less than a thickness of a portion of the base layer in the first region, a surface, distal from the base substrate, in surfaces of the base layer is a flat surface, and a surface, proximal to the base substrate, in the surfaces of the base layer is provided with at least one concave portion, the at least one concave portion being in one-to-one correspondence with the at least one convex portion;
forming a display film layer on a side of the base layer distal from the base substrate;
forming an encapsulation layer on a side of the display film layer distal from the base layer, wherein a surface of the encapsulation layer distal from the display film layer is provided with at least one concave portion, an orthographic projection of the at least one concave portion on the base substrate being in the second region;
forming a polarization layer on a side of the encapsulation layer distal from the display film layer, wherein the base layer, the display film layer, the encapsulation layer, and the polarization layer form the plurality of functional layers; and
stripping off the base substrate.

16. The method according to claim 15, wherein said forming the encapsulation layer on the side of the display film layer distal from the base layer, the surface of the encapsulation layer distal from the display film layer being provided with at least one groove comprises:
forming an encapsulation material layer on the side of the display film layer distal from the base layer; and
forming at least one concave portion on a surface of the encapsulation material layer distal from the display film layer to obtain the encapsulation layer.

17. The method according to claim 15, wherein the concave portion is in an elongated strip shape, and a boundary of a cross section of the concave portion is composed of at least one arc line segment, or a plurality of straight line segments, or a combination of arc line segments and straight line segments, the cross section being parallel to the thicknesswise direction of the display panel and perpendicular to a lengthwise direction of the concave portion.

18. The method according to claim 15, wherein a depth of the concave portion is in a value range from 500 nm to 50 μm, and a depth direction of the concave portion is parallel to the thicknesswise direction of the display panel.

19. The method according to claim 15, wherein a width of an opening surface of the concave portion is less than or equal to 10 μm.

20. A display device, comprising: a display panel, the display panel comprising a light-emitting region and a non-light-emitting region, wherein the non-light-emitting region comprises a target region having a first side edge and a second side edge that are oppositely arranged, wherein a thickness between the first side edge and the second side edge is smaller than a thickness of the light-emitting region along a thickness direction of the display panel; and a light-emitting unit and a pixel circuit are both disposed in the light-emitting region.
